(19) United States
(12) Patent Application Publication
(10) Pub. No.: US 2010/0212865 A1
(43) Pub. Date: Aug. 26, 2010

(54) HEAT DISSIPATING DEVICE USING HEAT PIPE

(76) Inventor: Sangcheol Lee, Seoul (KR)

Correspondence Address: Olson & Cepuritis, LTD., 20 NORTH WACKER DRIVE, 36TH FLOOR, CHICAGO, IL, 60606, US

(21) Appl. No.: 12/448,831

(22) PCT Filed: Jun. 25, 2008
(86) PCT No.: PCT/KR2008/003629

§ 371 Date: Jul. 9, 2009

(30) Foreign Application Priority Data
Oct. 8, 2007 (KR) 10-2007-0100852
Jun. 11, 2008 (KR) 10-2008-0054549

(51) Int. Cl. H05K 7/20

(52) U.S. Cl. 165/104.19

(57) ABSTRACT

There is provided a heat dissipating device using a heat pipe. The heat dissipating device includes a plurality of unit pipe loops. Each unit pipe loop includes: a heat absorbing part arranged adjacent to a heat source; and a heat dissipating part which is connected with the heat absorbing part and dissipates heat transferred from the heat absorbing part. A working fluid is to be provided inside the heat absorbing part and the heat dissipating part. The plurality of unit pipe loops being arranged radially with respect to the heat source.

### TECHNICAL FIELD

The present invention relates to a heat dissipating device, and more particularly, to a heat dissipating device using a heat pipe.

### BACKGROUND ART

In general, an electronic component such as a central processing unit (CPU) of a computer, a chip set of a video card, a power transistor, and a light-emitting diode (LED) generates heat in operation. When overheated, the electronic component may be malfunctioned or damaged. Accordingly, a heat dissipating device is required to prevent the electronic component from overheating.

The heat dissipating device dissipates heat generated in a heat source such as an electronic component to the outside to prevent overheat of the heat source.

Conventionally, there is disclosed a heat sink type heat dissipating device. The heat sink type heat dissipating device includes a heat absorbing part and a heat dissipating part. The heat absorbing part is disposed adjacent to the heat source to absorb heat generated from the heat source through thermal conduction. The heat dissipating part is provided with heat dissipating fins which are integrated with the heat absorbing part and dissipate the absorbed heat to the outside through heat exchange.

In the conventional heat sink type heat dissipating device having such a configuration, heat dissipating efficiency is determined according to the distance between the heat absorbing part and the heat dissipating part, a heat dissipating area of the heat dissipating fins, and thermal conductivity.

However, the conventional heat sink type heat dissipating device has difficulty maintaining a wide surface area of the heat dissipating fins considering that the size of the heat sink is required to get smaller and smaller according to the trend of integration and miniaturization of electronic components. Even if the surface area of the heat dissipating fins is enlarged, the distance between the heat absorbing part and the heat dissipating part becomes larger, thereby causing a limit to increasing heat dissipating efficiency.

Further, the conventional heat dissipating device should further include a fan rotating at a high speed to dissipate heat, and thus, causes problems of electric power consumption for driving the fan and a noise generated while the fan is being operated.

Furthermore, in the conventional heat dissipating device, it is difficult to make the thickness of the heat dissipating fins thin in consideration of structural stability and thermal conductivity, thereby causing a high manufacturing cost.

### DISCLOSURE OF INVENTION

### Technical Problem

Accordingly, it is an aspect of the present invention to provide a heat dissipating device which employs a heat pipe type thermal exchange mechanism to enhance heat dissipating efficiency, can secure an enlarged heat dissipating area regardless of the distance between a heat absorbing part and a heat dissipating part, can dissipate without a noise or with a low noise, and can secure high structural stability in thin thickness.

### Technical Solution

The foregoing and/or other aspects of the present invention can be achieved by providing a heat dissipating device including: a plurality of unit pipe loops, each unit pipe loop including: a heat absorbing part arranged adjacent to a heat source; and a heat dissipating part which is connected with the heat absorbing part and dissipates heat transferred from the heat absorbing part, a working fluid being to be provided inside the heat absorbing part and the heat dissipating part, the plurality of unit pipe loops being arranged radially with respect to the heat source.

The length of each unit pipe loop may be longer than a radial shortest straight line.

The heat dissipating part may include: a first heat dissipating part which is connected with the heat absorbing part and is arranged radially to have a length longer than the radial shortest straight line; and a second heat dissipating part which is connected with the first heat dissipating part and forms an outer circumferential wall of each unit pipe loop.

The heat dissipating part may further include at least one projection part between the first heat dissipating part and the second heat dissipating part.

At least an end part of each unit pipe loop may connected with a neighboring unit pipe loop.

The heat dissipating device may further include an auxiliary pipe loop which is disposed between the neighboring unit pipe loops and supports heat dissipation.

The heat dissipating device may further include a heat dissipating member which is coupled to each unit pipe loop.

The heat dissipating member may include a guide part which guides flow of the dissipated heat.

The heat dissipating device may further include a mount which is disposed adjacent to the heat source, and to which the plurality of unit pipe loops are installed.

The heat dissipating device may further include a holder which is coupled to the mount with the plurality of unit pipe loops being interposed therebetween.

The heat dissipating device may further include a fan which is installed adjacent to the heat dissipating part.

Each unit pipe loop may include a first pipe member and a second pipe member which have a first end part and a second end part, respectively. Here, the first end part of the first pipe member may be coupled to the first end part of the second pipe member, and the second end part of the first pipe member may be coupled to the second end part of the second pipe member of the neighboring unit pipe loop.

One of the end parts of the first pipe member and the end parts of the second pipe member, which are coupled each other, may be expanded in diameter.

The end parts of the first pipe member and the second pipe member may be coupled each other by soldering.

Additional aspects of the present invention will be set forth in part in the description which follows and, in part, will be obvious from the description, or may be learned by practice of the present invention.

### Advantageous Effects

First, a heat dissipating device according to the present invention employs a heat pipe mechanism having high heat dissipating efficiency, to thereby have a variety of sizes and shapes in accordance with surrounding space of a heat source.

Second, although the heat dissipating device according to the present invention employs a hollow pipe loop thinner in thickness than the conventional heat dissipating fins, its structural stability can be secured, thereby reducing consumption of material.

Third, the heat dissipating device according to the present invention employs pipe loops arranged radially with respect to a heat source to dissipate heat in multiple directions, thereby enhancing heat dissipating efficiency without a fan. Also, even in the case that the heat dissipating device includes the fan, high heat dissipating efficiency can be secured with a low rotational speed of the fan, thereby reducing noises.

Fourth, in the heat dissipating device according to the present invention, a first pipe member and a second pipe member are separately provided and then connected each other to form a unit pipe loop, thereby enhancing the productivity.

Fifth, the heat dissipating device according to the present invention provides the unit pipe loop in a variety of shapes such as spiral, serpentine and other waveforms, thereby enlarging a heat dissipating area of the unit pipe loop.

### BRIEF DESCRIPTION OF THE DRAWINGS

The above and/or other aspects of the present invention will become apparent and more readily appreciated from the following description of the exemplary embodiments, taken in conjunction with the accompanying drawings, in which:

FIG. 1 is an exploded perspective view illustrating a heat dissipating device according to a first exemplary embodiment of the present invention;

FIG. 2 is a perspective view illustrating unit pipe loops and auxiliary pipe loops of the heat dissipating device according to the first exemplary embodiment of the present invention;

FIG. 3 is a plane view illustrating the unit pipe loops and the auxiliary pipe loops of the heat dissipating device in FIG. 2 ;

FIG. 4 is an exploded perspective view illustrating a heat dissipating device according to a second exemplary embodiment of the present invention;

FIG. 5 illustrates a main part of a heat dissipating device according to a third exemplary embodiment of the present invention;

FIG. 6 is a sectional view taken along a line VI-VI in FIG. 5.

FIG. 7 is a perspective view illustrating unit pipe loops of a heat dissipating device according to a fourth exemplary embodiment of the present invention;

FIGS. 8 and 9 are exploded perspective views illustrating main parts of a heat dissipating device according to a fifth exemplary embodiment of the present invention;

FIG. 10 is a perspective view illustrating a heat dissipating device according to a sixth exemplary embodiment of the present invention;

FIG. 11 is an exploded perspective view illustrating a heat dissipating device according to a seventh exemplary embodiment of the present invention;

FIG. 12 is a plane view illustrating a plurality of unit pipe loops of the heat dissipating device according to the seventh exemplary embodiment of the present invention; and

FIG. 13 illustrates the unit pipe loops of the heat dissipating device according to the seventh exemplary embodiment of the present invention.

### BEST MODE FOR CARRYING OUT THE INVENTION

Reference will now be made in detail to the embodiments of the present invention, examples of which are illustrated in the accompanying drawings, wherein like reference numerals refer to like elements throughout. The exemplary embodiments are described below so as to explain the present invention by referring to the figures.

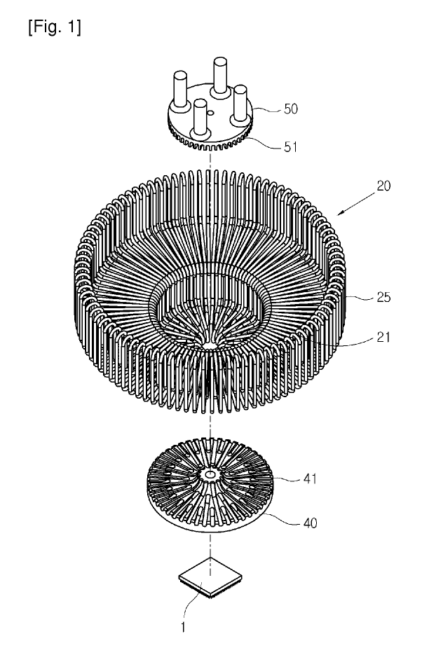

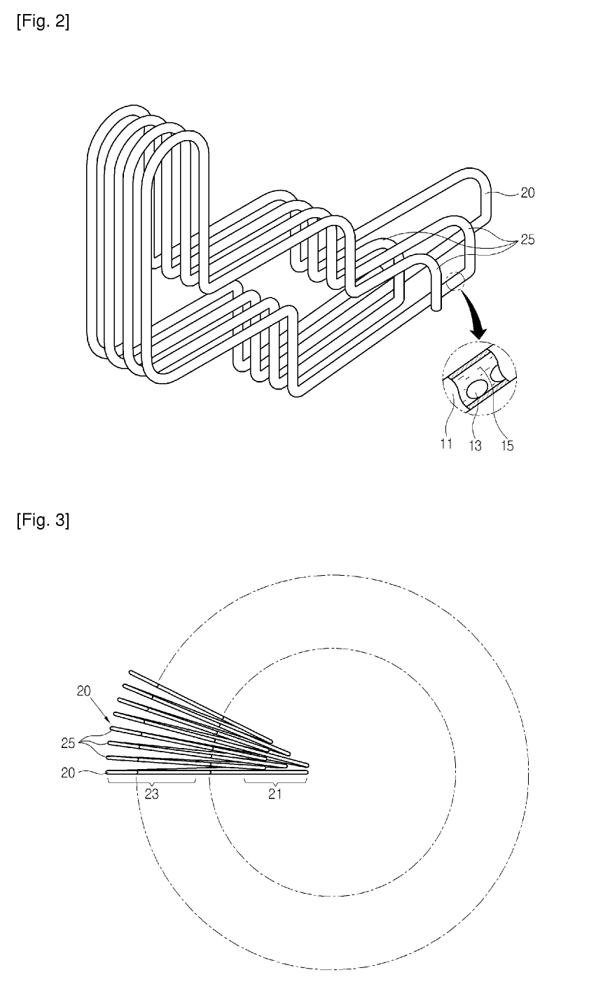

FIG. 1 is an exploded perspective view illustrating a heat dissipating device according to a first exemplary embodiment of the present invention; FIG. 2 is a perspective view illustrating a unit pipe loop and an auxiliary pipe loop of the heat dissipating device according to the first exemplary embodiment of the present invention; and FIG. 3 is a plane view illustrating the unit pipe loop and the auxiliary pipe loop in FIG. 2.

Referring to FIGS. 1 through 3, the heat dissipating device according to the first exemplary embodiment of the present invention includes a plurality of unit pipe loops 20 which are arranged radially to be adjacent to each other. The respective unit pipe loops 20 are disposed radially with respect to a heat source 1 (see FIG. 1). Accordingly, heat generated in the heat source 1 can be dissipated radially in multiple directions, thereby enhancing heat dissipating efficiency.

Here, the heat source 1 may include an electronic component such as a CPU, a chip set of a video card, a power transistor, and an LED. The size and the shape of the heat dissipating device may be varied according to the kind or the shape of the heat source 1.

As shown in FIG. 3, each of the unit pipe loops 20 includes a heat absorbing part 21 and a heat dissipating part 23. As shown in FIG. 2, inside the heat absorbing part 21 and the heat dissipating part 23 are provided a working fluid 15 with bubbles 13. The heat absorbing part 21 is disposed adjacent to the heat source 1 to absorb heat generated from the heat source 1. The heat dissipating part 23 is extended from the heat absorbing part 21 to the outside of a radial structure to dissipate the heat transferred from the heat absorbing part 21 to the outside.

Each of the unit pipe loops 20 is, desirably but not necessarily, made of metal such as copper and aluminum which have high thermal conductivity. Accordingly, heat from the heat source 1 can be conducted to the unit pipe loops 20 at a high speed and the volume of the bubbles 13 in the inside thereof can be changed quickly.

Each of the unit pipe loops 20 may have the shape of an open loop, and may be connected with or separated from the neighboring unit pipe loops 20. All or some of the plurality of unit pipe loops 20 may be connected with each other. In the case that all the unit pipe loops 20 connected with each other, the unit pipe loops 20 may have the shape of a single open loop or a single closed loop. In the case of the single open loop, opposite end parts thereof are sealed.

The plurality of unit pipe loops 20 may be separated into two or more groups which perform independent heat dissipation. The unit pipe loops 20 which belong to each group may be connected each other.

Between the neighboring unit pipe loops 20 may be provided an auxiliary pipe loop 25 which is spaced from the heat source 1. FIG. 2 illustrates three auxiliary pipe loops 25 which have different lengths beside one neighboring unit pipe loop 20. The auxiliary pipe loops 25 support heat dissipation between the neighboring unit pipe loops 20, thereby enhancing heat dissipating efficiency. The number and the length of the auxiliary pipe loops 25 may be changed variously according to the need of design.

Each of the pipe loops forms a heat pipe which uses fluid dynamic pressure (FDP), for example, an oscillating capillary tube heat pipe. Hereinafter, an operational principle of the oscillating capillary tube heat pipe as an example of the fluid dynamic pressure heat pipe will be briefly described by referring to FIG. 2.

As shown in FIG. 2, the oscillating capillary tube heat pipe has a configuration in which the inside of a fine tube 11 is sealed after the working fluid 15 is provided into the inside of the fine tube 11 so that bubbles 13 are generated therein in a pre-determined ratio. The heat pipe has a heat transfer mechanism which transfers heat as a latent heat by volume expansion and condensation of the bubbles 13 and the working fluid 15.

While nucleate boiling takes place as much as the amount of heat absorbed in the heat absorbing part 21, the bubbles 13 in the heat absorbing part 21 expand in volume. At this time, as the fine tube 11 maintains a uniform internal volume, the bubbles 13 in the heat dissipating part 23 contract in volume as much as the bubbles 13 in the heat absorbing part 21 are expanded. Accordingly, pressure equilibrium inside the fine tube 11 collapses, and thus, flow accompanying oscillations of the working fluid 15 and the bubbles 13 is generated in the fine tube 11. Accordingly, the heat pipe performs latent heat transfer by temperature change caused by the volume change of the bubbles 13, thereby performing heat dissipation.

The oscillating capillary tube heat pipe can be manufactured easily since it has no wick. Also, the oscillating capillary tube heat pipe has an advantage of less restriction in installation in comparison with a thermosyphon heat pipe having a configuration in which a heat dissipating part has to be disposed below a heat absorbing part. Also, the oscillating capillary tube heat pipe has a heat transfer method different from a heat sink type heat dissipating device and has no structural limitation, and accordingly, may have various sizes according to the kind or the shape of the heat source.

Referring to FIG. 1, the heat dissipating device according to the present exemplary embodiment may further include a mount 40 and a holder 50 for installation of the plurality of unit pipe loops 20. On the upper surface of the mount 40 are formed install grooves 41 into which the unit pipe loops 20 are fitted. The unit pipe loops 20 can be fitted into the install grooves 41 and maintains the entire shape thereof. The heat source 1 may be coupled to a lower surface of the mount 40.

The holder 50 is coupled to the mount 40, with the plurality of unit pipe loops 20 being interposed therebetween, to support the unit pipe loops 20. On its lower surface are formed coupling grooves 51, into which the unit pipe loops 20 are fitted.

As described above, the unit pipe loops 20 can be stably fitted into the install grooves 41 of the mount 40 and the coupling grooves 51 of the holder 50, thereby maintaining the entire shape thereof.

In the case that the auxiliary pipe loop 25 is disposed between the neighboring unit pipe loops 20, the auxiliary pipe loop 25 may be coupled to the mount 40 and the holder 50 in a similar way.

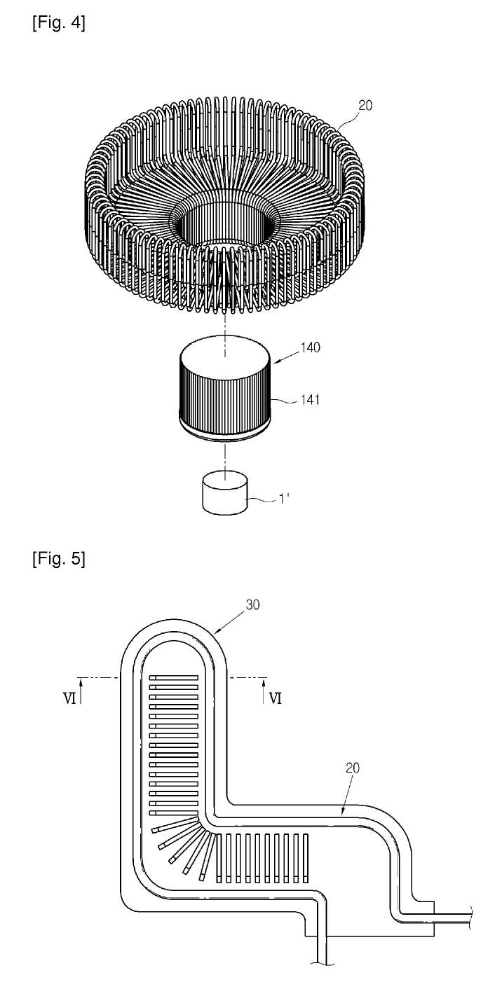

FIG. 4 illustrates a heat dissipating device according to a second exemplary embodiment of the present invention.

Referring to FIG. 4, a mount 140 according to the present embodiment has a cylindrical shape. On the outer circumference thereof are formed install grooves 141, into which the unit pipe loops 20 are fitted. In this case, the heat source 1′ may be coupled to a lower surface or an upper surface of the mount 140. The heat dissipating device in FIG. 4 is different in the shape of the unit pipe loops 20 and in the shape of the heat source 1′ as compared with the heat dissipating device in FIG. 1. That is, the shape of the mount may be modified variously according to the shape of the unit pipe loops, and the kind or the shape of the heat source. In the case that the auxiliary pipe loop 25 is disposed between the neighboring unit pipe loops 20, the auxiliary pipe loops 25 may be coupled to the mount 140.

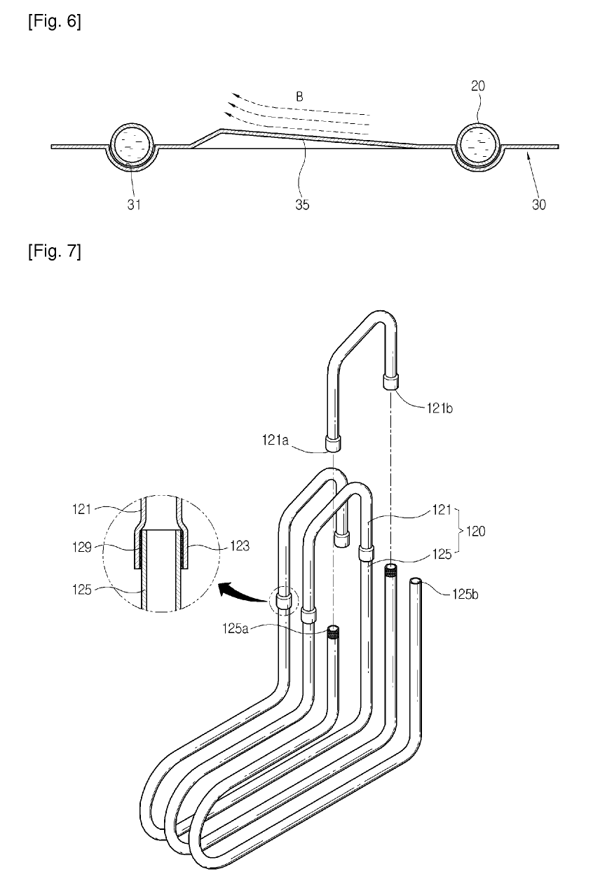

FIG. 5 illustrates a main part of a heat dissipating device according to a third exemplary embodiment of the present invention, and FIG. 6 is a sectional view taken along a line VI-VI in FIG. 5.

Referring to FIGS. 5 and 6, the heat dissipating device according to the present embodiment further includes a heat dissipating member 30 for heat dissipation, as compared with the preceding embodiments. The heat dissipating member 30 is coupled to each of the unit pipe loops 20. The heat dissipating member 30 may include a groove 31 into which each unit pipe loop 20 is fitted. Each unit pipe loop 20 and the heat dissipating member 30 may be coupled in known various coupling methods. The heat dissipating member 30 may include a guide part 35. The guide part 35 is protruded on one surface or opposite surfaces of the heat dissipating member 30, to increase a heat dissipating area of the heat dissipating member 30 and to guide flow of dissipated heat. FIG. 6 illustrates the guide part 35 protruded on the upper surface of the heat dissipating member 30 as an example. In this case, flow of the heat may be guided along an arrow ‘B’ direction on the upper surface of the heat dissipating member 30. Accordingly, a heat dissipating direction may be adjusted to be suitable for arrangement of an apparatus to which the heat dissipating device according to the present invention is applied. The heat dissipating member 30 may be installed between the unit pipe loops 20, or in the auxiliary pipe loops 25.

FIG. 7 is an exploded perspective view illustrating a main part of a heat dissipating device according to a fourth exemplary embodiment of the present invention.

Referring to FIG. 7, each unit pipe loop 120 includes a first pipe member 121 and a second pipe member 125. The first pipe member 121 has a downward bent shape and open opposite end parts, that is, a first end part 121a and a second end part 121b.

The second pipe member 125 has an upward bent shape and open opposite end parts, that is, a first end part 125a and a second end part 125b. The second pipe member 125 is coupled to the first pipe member 121 to form an open loop.

More particularly, the first end part 121a of the first pipe member 121 is coupled to the first end part 125a of the second pipe member 125 of the same unit pipe loop 120, and the second end part 121b of the first pipe member 121 is coupled to the second end part 125b of the second pipe member 125 of the neighboring unit pipe loop 120.

When the first end part 121a of the first pipe member 121 and the first end part 125a of the second pipe member 125 are coupled, and the second end part 121b of the first pipe member and the second end part 125b of the second pipe member 125 are coupled, the end parts 121a and 121b of the first pipe member 121 may be expanded widely to fit the end parts 125a and 125b of the second pipe member 125 by a blow process for easy sealing and coupling.

To the outer circumference of the end parts 125a and 125b of the second pipe member 125 may be provided an adhesive member 129. The adhesive member 129, for example, may be provided as a solder ring. Accordingly, the corresponding end parts of the first pipe member 121 and the second pipe member 125 may be coupled by soldering, to thereby form a unit pipe loop.

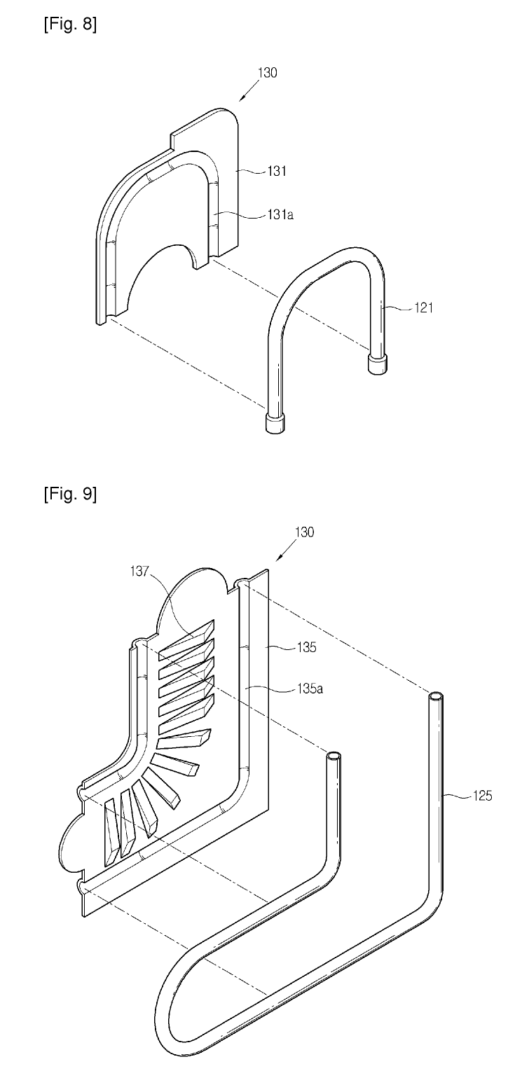

FIGS. 8 and 9 illustrate main parts of a heat dissipating device according to a fifth exemplary embodiment of the present invention.

Referring to FIGS. 8 and 9, a heat dissipating member 130 may be coupled to at least one of the first pipe member 121 and the second pipe member 125. The heat dissipating member 130 may include a first member 131 which is coupled to the first pipe member 121 and a second member 135 which is coupled to the second pipe member 125.

The first member 131 and the second member 135 each have a groove 131a and a groove 135a, into which the first and the second pipe members 121 and 125 are fitted respectively. Further, the first and the second members 131 and 135 may respectively include a guide part (see 137 in FIG. 9) which increases a heat dissipating area and guides flow of dissipated heat.

With this configuration, a manufacturing process of the unit pipe loop 120 can be automated, thereby enhancing productivity.

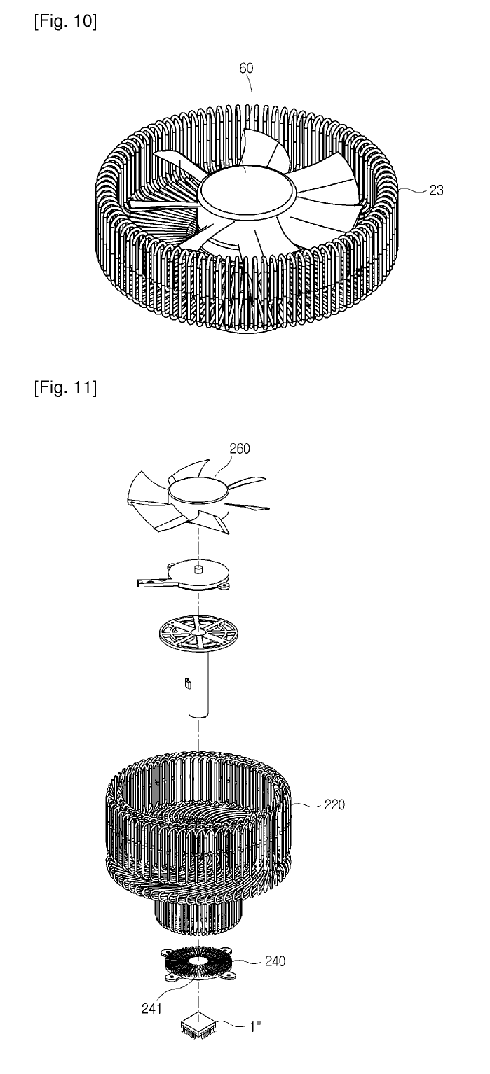

Referring to FIG. 10, a heat dissipating device according to a sixth exemplary embodiment of the present invention may further include a fan 60, as compared with the preceding embodiments. The fan 60 is disposed adjacent to the heat dissipating part 23 to expedite dissipation of heat by the heat dissipating part 23, thereby enhancing heat dissipating efficiency. The fan 60 rotates in a relatively low speed in comparison with the conventional heat dissipating device, thereby reducing a noise generated while the fan 60 rotates and reducing electric power consumption.

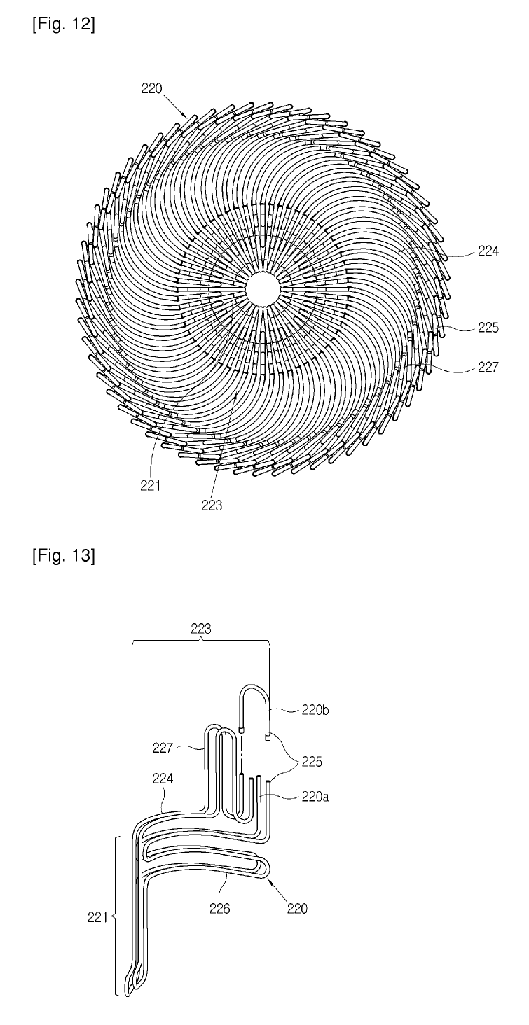

FIG. 11 is an exploded perspective view illustrating a heat dissipating device according to a seventh exemplary embodiment of the present invention, FIG. 12 is a plane view illustrating a plurality of unit pipe loops arranged radially in the heat dissipating device according to the seventh exemplary embodiment of the present invention, and FIG. 13 illustrates the unit pipe loops of the heat dissipating device according to the seventh exemplary embodiment of the present invention.

Referring to FIGS. 11 through 13, the heat dissipating device according to the present exemplary embodiment includes a plurality of unit pipe loops 220 arranged radially to be adjacent to each other. The respective unit pipe loops 220 are disposed to be adjacent radially with respect to a heat source 1″. Each of the unit pipe loops 220 includes a heat absorbing part 221 and a heat dissipating part 223. The heat dissipating part 223 includes a first heat dissipating part 224 which is extended from the heat absorbing part 221 and disposed approximately horizontally, and a second heat dissipating part 225 which is extended from the first heat dissipating part 224 and forms an outer circumferential wall of the unit pipe loop 220.

As shown in FIG. 12, the unit pipe loops 220 according to the present exemplary embodiment are different from the unit pipe loops according to the preceding exemplary embodiments (for example, refer to 20 in FIG. 1) in that the length of each of the unit pipe loops 220 is longer than the radial shortest straight line in a plane view. For this purpose, the unit pipe loops 220 may be formed in a helical shape, as shown in FIG. 12. Alternatively, the unit pipe loops 220 may be formed in the shape of other curved lines such as serpentine, in a straight line making a predetermined angle with respect to the shortest straight line, or in other various waveforms. Here, the part of the unit pipe loops 220, which is longer than the radial shortest straight line, includes the heat dissipating part 223, but may further include the heat absorbing part 221. In this way, the length of each unit pipe loop 220, in particular, the length of the heat dissipating part 223 can be provided relatively long, thereby increasing a heat dissipating area.

As shown in FIG. 13, the heat dissipating part 223 may further include at least one projection part 226 and 227. The first projection part 226 is projected to be approximately parallel with the first heat dissipating part 224, and the second projection part 227 is projected to be approximately parallel with the second heat dissipating part 225, but projecting directions of the projection parts 226 and 227 may be changed variously.

The heat dissipating device according to the present exemplary embodiment may further include a mount 240, a first pipe member 220a and a second pipe member 220b, a fan 260, and other components (not shown), similar to the preceding exemplary embodiments.

Although a few exemplary embodiments of the present invention have been shown and described, it will be appreciated by those skilled in the art that changes may be made in these embodiments without departing from the principles and spirit of the invention, the scope of which is defined in the appended claims and their equivalents.

### INDUSTRIAL APPLICABILITY

The heat dissipating device according to the present invention can be widely used to prevent overheat of an electronic component such as a CPU of a computer, a chip set of a video card, a power transistor, an LED.

1. A heat dissipating device comprising:
a plurality of unit pipe loops,
each unit pipe loop comprising: a heat absorbing part arranged adjacent to a heat source; and a heat dissipating part which is connected with the heat absorbing part and dissipates heat transferred from the heat absorbing part,
a working fluid being to be provided inside the heat absorbing part and the heat dissipating part,
the plurality of unit pipe loops being arranged radially with respect to the heat source, and being connected with each other to form a single loop.

2. The heat dissipating device according to claim 1, wherein the length of each unit pipe loop is longer than a radial shortest straight line.

3. The heat dissipating device according to claim 2, wherein the heat dissipating part comprises: a first heat dissipating part which is connected with the heat absorbing part and is arranged radially to have a length longer than the radial shortest straight line; and a second heat dissipating part which is connected with the first heat dissipating part and forms an outer circumferential wall of each unit pipe loop.

4. The heat dissipating device according to claim 3, wherein the heat dissipating part further comprises at least one projection part between the first heat dissipating part and the second heat dissipating part.

5. The heat dissipating device according to claim 4, wherein at least one end part of each unit pipe loop is connected with a neighboring unit pipe loop.

6. The heat dissipating device according to claim 5, further comprising a auxiliary pipe loop which is disposed between the neighboring unit pipe loops and supports heat dissipation.

7. The heat dissipating device according to claim 6, further comprising a heat dissipating member which is coupled to each unit pipe loop.

8. The heat dissipating device according to claim 7, wherein the heat dissipating member comprises a guide part which guides flow of the dissipated heat.

9. The heat dissipating device according to claim 8, further comprising a mount which is disposed adjacent to the heat source, and to which the plurality of unit pipe loops are installed.

10. The heat dissipating device according to claim 9, further comprising a holder which is coupled to the mount with the plurality of unit pipe loops being interposed therebetween.

11. The heat dissipating device according to claim 10, further comprising a fan which is installed adjacent to the heat dissipating part.

12. The heat dissipating device according to claim 8, wherein each unit pipe loop comprises a first pipe member and a second pipe member which have a first end part and a second end part, respectively, and wherein the first end part of the first pipe member is coupled to the first end part of the second pipe member, and the second end part of the first pipe member is coupled to the second end part of the second pipe member of the neighboring unit pipe loop.

13. The heat dissipating device according to claim 12, wherein one of the end parts of the first pipe member and the end parts of the second pipe member, which are coupled each other, are expanded in diameter.

14. The heat dissipating device according to claim 13, wherein the end parts of the first pipe member and the second pipe member are coupled each other by soldering.

15. The heat dissipating device according to claim 1, wherein the plurality of unit pipe loops is connected with each other to form a single closed loop.
